(19) United States
(12) Patent Application Publication
(10) Pub. No.: US 2026/0107704 A1
(43) Pub. Date: Apr. 16, 2026

(54) CONTROLLING AUTO-DOPING IN EPITAXIALLY GROWN SILICON-CONTAINING MATERIALS

(71) Applicant: Applied Materials, Inc., Santa Clara, CA (US)

(72) Inventors: Arvind Kumar, Austin, TX (US); Arkka Bhattacharyya, San Jose, CA (US); Zuoming Zhu, Sunnyvale, CA (US); Abhishek Dube, Fremont, CA (US)

(73) Assignee: Applied Materials, Inc., Santa Clara, CA (US)

(21) Appl. No.: 18/960,281

(22) Filed: Nov. 26, 2024

Related U.S. Application Data
(60) Provisional application No. 63/708,073, filed on Oct. 16, 2024.

(51) Int. Cl. H01L 21/02; H10D 62/00

(52) U.S. Cl. CPC H10P 14/3411; H10D 62/01; H10P 14/3444; H10P 14/3602

(57) ABSTRACT

Exemplary semiconductor processing methods may include forming a barrier layer on a first source/drain material disposed on a substrate housed within a processing region of a semiconductor processing chamber. The first source/drain material may be doped with a dopant. The methods may include growing an epitaxial silicon-containing material on the barrier layer. The barrier layer may reduce an amount of diffusion of the dopant from the first source/drain material into the epitaxial silicon-containing material.

### CROSS-REFERENCE TO RELATED APPLICATIONS

This application claims the benefit of, and priority to U.S. Provisional Application Ser. No. 63/708,073, filed Oct. 16, 2024, which is hereby incorporated by reference in its entirety for all purposes.

### TECHNICAL FIELD

The present technology relates to methods and systems for semiconductor processing. More specifically, the present technology relates to systems and methods for controlling auto-doping in epitaxially grown silicon-containing materials.

### BACKGROUND

Integrated circuits are made possible by processes which produce intricately patterned material layers on substrate surfaces. Producing patterned material on a substrate requires controlled methods for forming and removing material. As device sizes continue to reduce, film characteristics may lead to larger impacts on device performance. Materials used to form layers of materials may affect operational characteristics of the devices produced. As material thicknesses continue to reduce, as-deposited characteristics of the films may have a greater impact on device performance.

Thus, there is a need for improved systems and methods that can be used to produce high quality devices and structures. These and other needs are addressed by the present technology.

### SUMMARY

Exemplary semiconductor processing methods may include forming a barrier layer on a first source/drain material disposed on a substrate housed within a processing region of a semiconductor processing chamber. The first source/drain material may be doped with a dopant. The methods may include growing an epitaxial silicon-containing material on the barrier layer. The barrier layer may reduce an amount of diffusion of the dopant from the first source/drain material into the epitaxial silicon-containing material.

In some embodiments, forming the barrier layer may include providing one or more deposition precursors to the processing region of the semiconductor processing chamber, and contacting the substrate with the one or more deposition precursors. The contacting may form the barrier layer. The dopant may be or include a Group V element. The dopant may be or include phosphorous (P). The barrier layer may be characterized by a thickness of less than or about 500 Å. The barrier layer may be characterized by a thickness of greater than or about 10 Å. The barrier layer may be or include one or more silicon-containing materials. The one or more silicon-containing materials may be doped with a Group III-V element. The barrier layer may be or include a carbon-doped silicon-containing material. The barrier layer may be formed at a temperature of less than or about 600° C. The methods may include, prior to forming the barrier layer, forming the first source/drain material on the substrate in the processing region of the semiconductor processing chamber. The methods may include, subsequent to forming the first source/drain material on the substrate in the processing region of the semiconductor processing chamber, performing a clean to remove residual dopant from the processing region. A pressure within the processing region may be maintained at greater than or about 5 Torr while growing the epitaxial silicon-containing material.

Some embodiments of the present technology may encompass semiconductor processing methods. The methods may include forming a first source/drain material on a substrate in a processing region of a semiconductor processing chamber. The first source/drain material may be doped with a dopant. The methods may include growing an epitaxial silicon-containing material on the first source/drain material. The epitaxial silicon-containing material may be formed at a temperature of less than or about 600° C.

In some embodiments, the methods may include forming a barrier layer of a silicon-containing material on the first source/drain material. The epitaxial silicon-containing material may be characterized by a dopant concentration of less than or about 1E20 atoms/cm³. The first source/drain material may be formed in a first semiconductor processing chamber. The epitaxial silicon-containing material may be grown in a second semiconductor processing chamber.

Some embodiments of the present technology may encompass semiconductor processing methods. The methods may include forming a first source/drain material on a substrate in a processing region of a semiconductor processing chamber. The first source/drain material may be doped with a Group V element. The methods may include performing a clean to remove residual Group V element from the processing region. The methods may include forming a barrier layer on the first source/drain material. The barrier layer may be formed at a first temperature of less than or about 600° C. The methods may include growing an epitaxial silicon-containing material on the barrier layer. The barrier layer may control an amount of diffusion of the Group V element from the first source/drain material into the epitaxial silicon-containing material.

In some embodiments, the barrier layer may be or include one or more silicon-containing materials. The barrier layer may be characterized by a thickness of less than or about 500 Å. The epitaxial silicon-containing material may be grown at a second temperature greater than the first temperature.

Such technology may provide numerous benefits over conventional systems and techniques. For example, embodiments of the present technology may reduce and/or prevent dopant diffusion from adjacent or nearby materials into epitaxially grown silicon-containing material. Additionally, the present technology, through a barrier layer or engineered growth conditions, may provide epitaxially grown silicon-containing material with a desired dopant profile. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma deposition system according to some embodiments of the present technology.

FIG. 3 shows operations in a semiconductor processing method according to some embodiments of the present technology.

FIGS. 4A-4E show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As semiconductor device sizes continue to reduce, the constituent films included within a structure may affect device performance, as well as fabrication of other materials being included in the device. Additionally, as demand increases, throughput and queue times become a point of emphasis. Thus, a demand exists for high-quality materials and structures that may be formed both quickly and efficiently.

Conventional technologies, prior to being limited by reduced device sizes, may not have been as dependent on controlled dopant concentrations in epitaxial silicon-containing material, such as silicon channel material in three-dimensional dynamic random-access memory (3D DRAM) structures. However, with reduced feature sizes, diffusion of a dopant from adjacent or nearby material may affect device performance. Conventional technologies have not been able to address unwanted or uncontrolled dopant diffusion.

The present technology overcomes these issues by forming a barrier layer between epitaxial silicon-containing material, such as silicon channel material in 3D DRAM structures, and a source of dopant diffusion, such as source/drain material. Additionally or alternatively, the present technology may adjust growth conditions to prevent the unwanted or uncontrolled dopant diffusion. In certain situations, the present technology may combine the barrier layer and growth conditions to drastically reduce and/or entirely prevent diffusion of dopant material into the epitaxial silicon-containing material.

Although the remaining disclosure will routinely identify specific processes utilizing the disclosed technology, it will be readily understood that the systems and methods are equally applicable to other deposition and etching processes as may occur in the described chambers or any other chamber. Accordingly, the technology should not be considered to be so limited as for use with these specific deposition processes or chambers alone. The disclosure will discuss one set of possible chambers that may be used to perform processes according to embodiments of the present technology before additional variations and adjustments to this system according to embodiments of the present technology are described.

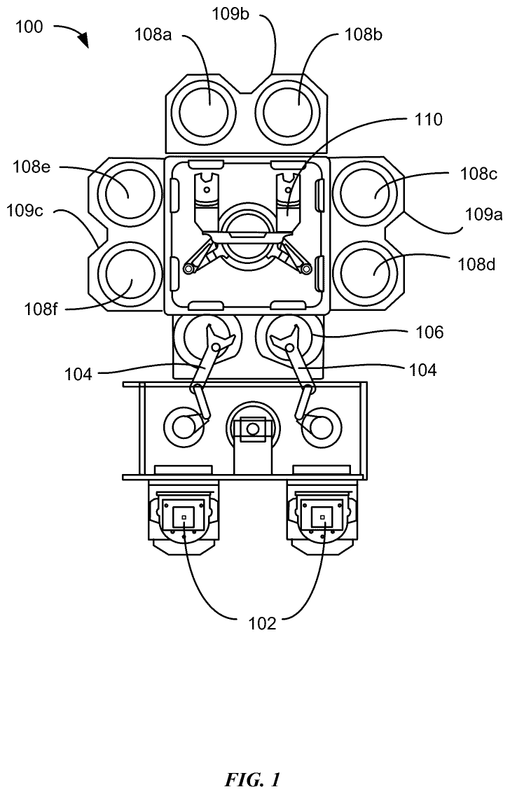

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the semiconductor processing chambers 108a-f, positioned in tandem sections 109a-c. A second robotic arm 110 may be used to transport the substrate wafers from the holding area 106 to the semiconductor processing chambers 108a-f and back. Each semiconductor processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The semiconductor processing chambers 108a-f may include one or more system components for depositing, annealing, curing, and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

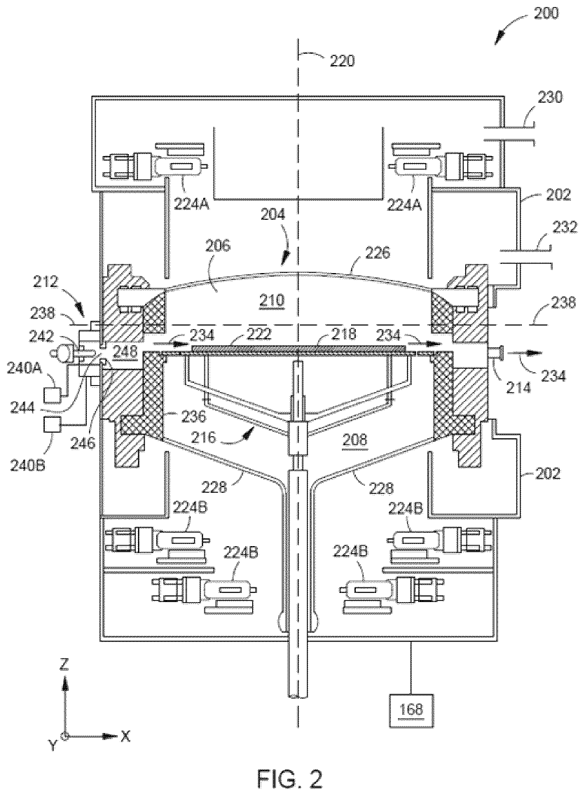

FIG. 2 illustrates a cross sectional view of a processing chamber 200, according to one or more embodiments. In one or more embodiments, the processing chamber 200 is configured to conduct an epitaxial (Epi) deposition or growth process as further discussed below. Processing chamber 200 may illustrate a processing chamber 108a-f that may be fitted in one or more of tandem sections 109a-c described above, and which may include faceplates or other components or assemblies according to embodiments of the present technology.

The processing chamber 200 includes a housing structure 202 made of a process resistant material, such as aluminum or stainless steel, for example 216L stainless steel. The housing structure 202 encloses various functioning elements of the processing chamber 200, such as a chamber 204, which includes an upper chamber 206, and a lower chamber 208, in which a processing volume 210 is contained. The chamber 204 can be, for example, a quartz chamber. Reactive species are provided to the chamber 204 by a gas distribution assembly 212, and processing byproducts are removed from the processing volume 210 by an outlet port 214, which is typically in communication with a vacuum source (not shown).

A substrate support 216 is adapted to receive a substrate 218 that is transferred to the processing volume 210. The substrate support 216 is disposed along a longitudinal axis 220 of the processing chamber 200. The substrate support 216 may be made of a ceramic material or a graphite material coated with a silicon material, such as silicon carbide, or other process resistant material. Reactive species from precursor reactant materials are applied to a surface 222 of the substrate 218, and byproducts may be subsequently removed from the surface 222 of the substrate 218. Heating of the substrate 218 in the processing volume 210 may be provided by radiation sources, such as upper heat sources 224A (e.g., lamps) and lower heat sources 224B (e.g., lamps). The present disclosure contemplates that other heat sources may be used (in addition to or in place of the lamps) for the various heat sources described herein. For example, resistive heaters, light emitting diodes (LEDs), and/or lasers may be used for the various heat sources described herein.

In one or more embodiments, the upper heat sources 224A and the lower heat sources 224B are infrared (IR) lamps. Non-thermal energy or radiation from the heat sources 224A and 224B travels through an upper transparent plate 226 (such as an upper quartz window) of the upper chamber 206, and through a lower transparent plate 228 (such as a lower quartz window) of the lower chamber 208. Cooling gases for the upper chamber 206, if needed, enter through an inlet 230 and exit through an outlet 232. Precursor reactant materials, as well as diluent, purge and vent gases for the processing chamber 200, enter through the gas distribution assembly 212 and exit through the outlet port 214. While the upper transparent plate 226 is shown as being curved or convex, the upper transparent plate 226 may be planar or concave as the pressure on both sides of the upper transparent plate 226 is substantially the same (e.g., at atmospheric pressure).

The low wavelength radiation in the processing volume 210, which is used to energize reactive species and assist in adsorption of reactants and desorption of process byproducts from the surface 222 of the substrate 218, typically ranges from about 0.8 μm to about 1.2 μm, for example, between about 0.95 μm to about 1.05 μm, with combinations of various wavelengths being provided, depending, for example, on the composition of the film which is being epitaxially grown.

The component gases enter the processing volume 210 via the gas distribution assembly 212. Gas flows from the gas distribution assembly 212 and exits through the outlet port 214 as shown generally by a flow path 234. Combinations of component gases, which are used to clean/passivate a substrate surface, or to form the silicon and/or germanium-containing film that is being epitaxially grown, are typically mixed prior to entry into the processing volume 210. The overall pressure in the processing volume 210 may be adjusted by a valve (not shown) on the outlet port 214. At least a portion of the interior surface of the processing volume 210 is covered by a liner 236. In one or more embodiments, the liner 236 comprises a quartz material that is opaque. In this manner, the chamber wall is insulated from the heat in the processing volume 210.

The temperature of surfaces in the processing volume 210 may be controlled within a temperature range of about 200° C. to about 600° C., or greater, by the flow of a cooling gas, which enters through the inlet 230 and exits through the outlet 232, in combination with radiation from the upper heat sources 224A positioned above the upper transparent plate 226. The temperature in the lower chamber 208 may be controlled within a temperature range of about 200° C. to about 600° C. or greater, by adjusting the speed of a blower unit which is not shown, and by radiation from the lower heat sources 224B disposed below the lower chamber 208. The pressure in the processing volume 210 may be between about 0.1 Torr to about 600 Torr, such as between about 5 Torr to about 30 Torr.

The temperature on the surface 222 of the substrate 218 may be controlled by power adjustment to the lower heat sources 224B in the lower chamber 208, or by power adjustment to both the upper heat sources 224A overlying the upper transparent plate 226, and the lower heat sources 224B in the lower chamber 208. The power density in the processing volume 210 may be between about 40 W/cm² to about 400 W/cm², such as about 80 W/cm² to about 120 W/cm². Other power densities are contemplated.

In one or more embodiments, the gas distribution assembly 212 is disposed normal to, or in a radial direction 238 relative to, the longitudinal axis 220 of the processing chamber 200 or the substrate 218. In this orientation, the gas distribution assembly 212 is adapted to flow process gases in the radial direction 238 across, or parallel to, the surface 222 of the substrate 218. In one processing application, the process gases are preheated at the point of introduction to the processing chamber 200 to initiate preheating of the gases prior to introduction to the processing volume 210, and/or to break specific bonds in the gases. In this manner, surface reaction kinetics may be modified independently from the thermal temperature of the substrate 218.

In operation, precursors used to form silicon (Si) and silicon germanium (SiGe) blanket or selective epitaxial films are provided to the gas distribution assembly 212 from one or more gas sources 240A and 240B. IR lamps 242 (one is shown in FIG. 2) may be utilized to heat the precursors within the gas distribution assembly 212 as well as along the flow path 234. The gas sources 240A, 240B may be coupled the gas distribution assembly 212 in a manner adapted to facilitate introduction zones within the gas distribution assembly 212, such as a radial outer zone and a radial inner zone between the outer zones when viewed in from a top plan view. The gas sources 240A, 240B may include valves to control the rate of introduction into the zones.

The gas sources 240A, 240B may include silicon precursors such as silanes, including silane (SiH₄), disilane (Si₂H₆,), trisilane (Si₃H₈), tetrasilane (Si₄H₁₀), dichlorosilane (SiH₂Cl₂), trichlorosilane, hexachlorodisilane (Si₂Cl₆), dibromosilane (SiH₂Br₂), higher order silanes, derivatives thereof, and combinations thereof. The gas sources 240A, 240B may also include germanium containing precursors, such as germane (GeH₄), digermane (Ge₂H₆), germanium tetrachloride (GeCl₄), dichlorogermane (GeH₂Cl₂), derivatives thereof, and combinations thereof. The silicon and/or germanium containing precursors may be used in combination with hydrogen chloride (HCl), chlorine gas (Cl₂), hydrogen bromide (HBr), and combinations thereof. The gas sources 240A, 240B may include one or more of the silicon and germanium containing precursors in one or both of the gas sources 240A, 240B.

The precursor materials enter the processing volume 210 through openings or holes 244 (one is shown in FIG. 2) in the perforated plate 246 in this excited state, which in one embodiment is a quartz material, having the holes 244 formed therethrough. The perforated plate 246 is transparent to IR energy, and may be made of a clear quartz material. In one or more embodiments, the perforated plate 246 may be any material that is transparent to IR energy and is resistant to process chemistry and other processing chemistries. The energized precursor materials flow toward the processing volume 210 through the holes 244 in the perforated plate 246, and through channels 248 (one is shown in FIG. 2). A portion of the photons and non-thermal energy from the IR lamps 242 also passes through the holes 244, the perforated plate 246, and channels 248 facilitated by a reflective material and/or surface disposed on the interior surfaces of the gas distribution assembly 212, thereby illuminating the flow path 234 of the precursor materials. In this manner, the vibrational energy of the precursor materials may be maintained from the point of introduction to the processing volume 210 along the flow path.

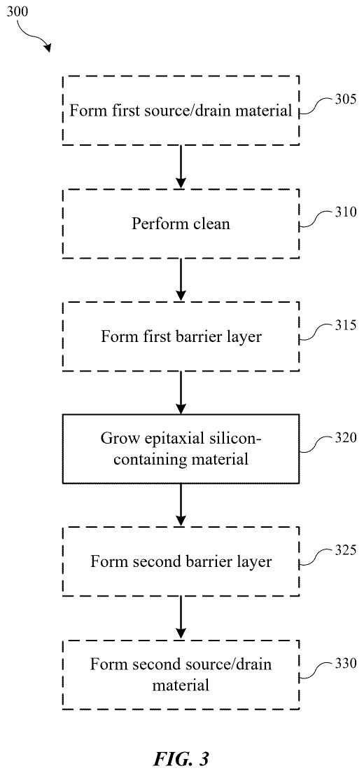

FIG. 3 shows exemplary operations in a semiconductor processing method 300 according to some embodiments of the present technology. The method 300 may be performed in a variety of processing chambers, including processing chamber 200 described above. Method 300 may include one or more operations prior to the initiation of the stated method operations, including front end processing, deposition, etching, polishing, cleaning, or any other operations that may be performed prior to the described operations. The method may include a number of optional operations as denoted in the figure, which may or may not specifically be associated with the method according to the present technology. For example, many of the operations are described in order to provide a broader scope of the semiconductor process, but are not critical to the technology, or may be performed by alternative methodology as will be discussed further below.

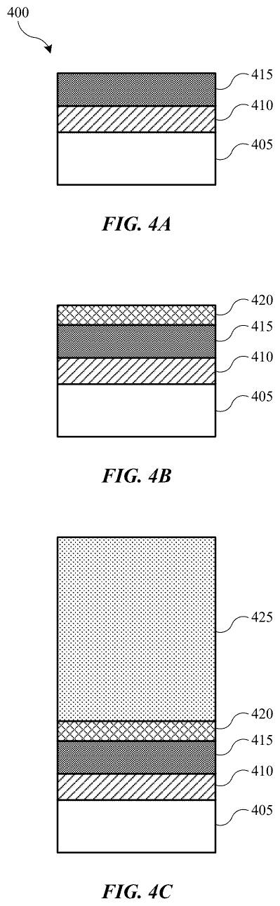

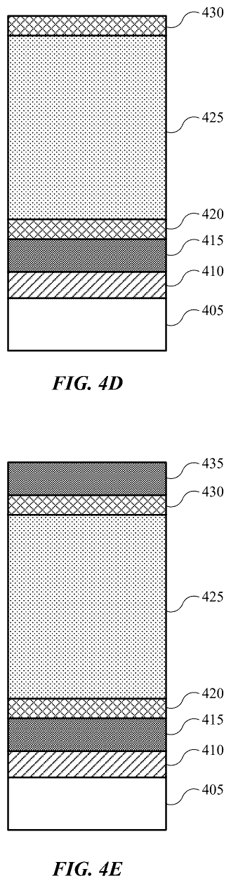

Method 300 may involve optional operations to develop the semiconductor structure to a particular fabrication operation. Although the method 300 may be performed on a base structure, in some embodiments, the method 300 may be performed subsequent to other material formation or removal. For example, any number of deposition, masking, or removal operations may be performed to produce any transistor, memory, or other structural aspects on a substrate. The substrate may be disposed on a substrate support, which may be positioned within a processing region of a semiconductor processing chamber. The operations may be performed in the same chamber in which aspects of method 300 may be performed, and one or more operations may also be performed in one or more chambers on a similar platform as a chamber in which operations of method 300 may be performed, or on other platforms. Method 300 describes the operations shown schematically in FIGS. 4A-4E, the illustrations of which will be described in conjunction with the operations of method 300. It is to be understood that FIGS. 4A-4E illustrate only partial schematic views, and a substrate may contain any number of transistor sections having aspects as illustrated in the figures.

As shown in FIG. 4A, structure 400 may include a substrate 405. The substrate 405 may be made of or contain silicon or some other semiconductor substrate material. In embodiments, the substrate 405 may be a bit line in a 3D DRAM structure. One or more layers of material may be formed on the substrate 405. The layers of material may include, for example, a first layer of material 410. The first layer of material 410 may be a sacrificial material, such as a silicon-and-germanium-containing material. In subsequent processing, the first layer of material 410 may be removed and replaced with another material. While illustrated as directly overlying the substrate 405, it is contemplated that the first layer of material 410 may be separated from the substrate 405 by one or more intervening layers. In embodiments, method 300 may include forming source/drain material at optional operation 305. As illustrated in FIG. 4A, optional operation 305 may form first source/drain material 415. The first source/drain material 415 may overly the first layer of material 410. The first source/drain material 415 may be a doped silicon-containing material. In embodiments, the first source/drain material 415 may be doped with any Group V element. For example, the first source/drain material 415 may be doped with nitrogen (N), phosphorus (P), arsenic (As), antimony (Sb), bismuth (Bi), or a combination thereof.

In embodiments, the first source/drain material 415, which may be source/drain material in a 3D DRAM structure, may be characterized by a high dopant concentration. For example, the first source/drain material 415 may be characterized by a dopant concentration of greater than or about 1E19 atoms/cm³, and may be characterized by greater than or about 5E19 atoms/cm³, greater than or about 1E20 atoms/cm³, greater than or about 5E20 atoms/cm³, greater than or about 1E21 atoms/cm³, or more. Without the present technology, at least a portion of the dopant in the first source/drain material 415 may diffuse into a subsequently formed silicon-containing material, such as a silicon channel in a 3D DRAM structure. This uncontrolled diffusion, which may be any diffusion or non-targeted diffusion, may impact device properties and performance.

After forming the first source/drain material 415, the processing region may be contaminated with the Group V element used to dope the first source/drain material 415. If left untreated, this Group V element may contaminate subsequent materials formed on the substrate 405. As such, method 300 may include performing a clean at optional operation 310. The clean at optional operation 310 may be any operation(s) used or useful in semiconductor processing to remove residual material or contaminants from the processing region. For example, the clean at optional operation 310 may include providing one or more cleaning precursors, such as a halogen-containing precursor, an oxygen-containing precursor, a hydrogen-containing precursor, a nitrogen-containing precursor, any other cleaning precursor, or any combination thereof to the processing region. In embodiments, remote plasma effluents of the cleaning precursors may be formed prior to being provided to the processing region. The cleaning precursors or, if formed, remote plasma effluents may then contact surface defining the processing region to react with and remove residual material or contaminants from the processing region.

The substrate 405 may be removed prior to performing the clean at optional operation 310 and may be replaced after the clean. If left in the processing region, the substrate 405 may interact with the clean precursors or, if formed, plasma effluents thereof, which may cause damage to the substrate 405 or materials on the substrate 405. The substrate 405 may be kept in vacuum during the clean, such that the substrate 405 and materials formed on the substrate 405 are not exposed to atmosphere.

As illustrated in FIG. 4B, optional operation 315 of method 300 may include forming a barrier layer 420. Forming the barrier layer 420 may include providing one or more deposition precursors to the processing region of the semiconductor processing chamber. Optionally, plasma effluents of the one or more deposition precursors may be formed. Then, the substrate 405 may be contacted with the one or more deposition precursors or, if formed, plasma effluents thereof. The contacting may form the barrier layer 420.

The barrier layer 420 may be formed over or directly on the first source/drain material 415. However, it is again contemplated that the barrier layer 420 may be separated from the first source/drain material 415 by one or more intervening layers. The barrier layer 420 may prevent diffusion of the dopant, such as any Group V element, in the first source/drain material 415 to layers that are subsequently deposited and as further discussed below. In embodiments, the barrier layer 420 may be a silicon-containing material or a stack of multiple silicon-containing materials. The silicon-containing material(s) forming the barrier layer 420 may be doped or undoped. Doped silicon-containing materials may include any Group III-V element. For example, the dopant may be boron (B), aluminum (Al), gallium (Ga), indium (In), carbon (C), germanium (Ge), nitrogen (N), or any other Group III-V element. In one exemplary embodiment, the barrier layer 420 may be a carbon-doped silicon-containing material, such as carbon doped silicon. The dopant may also be selected to assist with controlling an amount of dopant that may diffuse from the first source/drain material 415 to adjacent layers, such as silicon channel material discussed below.

The barrier layer 420 may be formed using any deposition method. For example, the barrier layer 420 may be formed using any thermal deposition method or any plasma-enhanced deposition method. For example, the barrier layer 420 may be formed using physical vapor deposition (PVD), chemical vapor deposition (CVD), plasma-enhanced chemical vapor deposition (PECVD), plasma-assisted CVD (PACVD), or any other deposition method.

The barrier layer 420 may be characterized by a thickness of less than or about 500 Angstrom (Å). A reduced thickness of the barrier layer 420 may be desired to minimize additional material in the structure 400. As such, the barrier layer 420 may be characterized by a thickness of less than or about 450 Å, and may be characterized by a thickness of less than or about 400 Å, less than or about 350 Å, less than or about 300 Å, less than or about 250 Å, less than or about 200 Å, ss than or about 150 Å, less than or about 100 Å, or less. However, the thickness of the barrier layer 420 may impact the amount of diffusion of the dopant from the first source/drain material 415. As such, greater thicknesses of the barrier layer 420 may further reduce diffusion. In embodiments, the barrier layer 420 may be characterized by a thickness of greater than or about 10 Å, and may be characterized by a thickness of greater than or about 50 Å, greater than or about 100 Å, greater than or about 150 Å, greater than or about 200 Å, greater than or about 250 Å, greater than or about 300 Å, or more.

The barrier layer 420 may be formed at a relatively low temperature, such as a first temperature. Reduced temperatures may reduce an energy of the dopant in the first source/drain material 415 below the energy necessary for the dopant to escape the first source/drain material 415. In embodiments, the barrier layer 420 may be formed at a temperature less than or about 650° C., and may be grown at a temperature less than or about 640° C., less than or about 620° C., less than or about 600° C., less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., or less.

In embodiments, the barrier layer 420 may be formed to allow for dopant engineering in subsequently formed materials, such as silicon-containing material, which may be a silicon channel in a 3D DRAM structure. Dopant engineering may refer to controlled diffusion of the dopant in the first source/drain material 415 through the barrier layer 420 and into the subsequently formed materials, such as a silicon channel in a 3D DRAM structure. To allow for a controlled amount of dopant diffusion, a thickness of the barrier layer 420 and material of the barrier layer 420 may be carefully selected. Additionally, the deposition of the barrier layer 420 may be controlled, with processing conditions selected to allow for desired dopant diffusion.

After forming the barrier layer 420, method 300 may include epitaxially growing silicon-containing material at operation 320. As illustrated in FIG. 4C, epitaxial silicon-containing material 425 may be formed over or directly on the barrier layer 420. However, it is again contemplated that the epitaxial silicon-containing material 425 may be separated from the barrier layer 420 by one or more intervening layers. By including the barrier layer 420, diffusion of the dopant from the first source/drain material 415 may be limited. As such, the epitaxial silicon-containing material 425 may be characterized by a reduced dopant concentration compared to conventional technologies that do not include a barrier between the first source/drain material 415 and the epitaxial silicon-containing material 425.

The growth of the epitaxial silicon-containing material 425 may also limit diffusion of the dopant from the first source/drain material 415 to the epitaxial silicon-containing material 425. In embodiments, the epitaxial silicon-containing material 425 may be formed using various silicon-containing precursors. The silicon-containing precursors may be or include, but are not limited to, silane (SiH₄), disilane (Si₂H₆), trisilane (Si₃H₈), tetrasilane (Si₄H₁₀), or other high-order silanes/silicon-containing precursors. Additional precursors, such as carrier gases or inert precursors, may also be provided with the silicon-containing precursor.

The epitaxial silicon-containing material 425 may be grown at a relatively high temperature, such as a second temperature greater than the first temperature. For example, subsequent to forming the first source/drain material 415 and/or the barrier layer 420, a temperature in the processing region may be increased to grow the epitaxial silicon-containing material 425. In embodiments, the epitaxial silicon-containing material 425 may be grown at a temperature greater than or about 300° C., and may be grown at a temperature greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 560° C., greater than or about 580° C., greater than or about 600° C., greater than or about 620° C., greater than or about 640° C., greater than or about 650° C., or more. Additionally, the epitaxial silicon-containing material 425 may be grown at a temperature less than or about 800° C., and may be grown at a temperature less than or about 750° C., less than or about 700° C., less than or about 680° C., less than or about 660° C., less than or about 650° C., less than or about 640° C., less than or about 620° C., less than or about 600° C., less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., or less. Temperatures within these ranges may reduce an energy of the dopant in the first source/drain material 415 below the energy necessary for the dopant to escape the first source/drain material 415 and diffuse into the epitaxial silicon-containing material 425. However, with the presence of the barrier layer 420, increased temperatures may be used to grow the epitaxial silicon-containing material 425, such that diffusion from the first source/drain material 415 may be at least partially blocked by the barrier layer 420.

The pressure at which the epitaxial silicon-containing material 425 may be grown may also reduce and/or prevent diffusion. For example, subsequent to forming the first source/drain material 415 and/or the barrier layer 420, a pressure in the processing region may be reduced to grow the epitaxial silicon-containing material 425. In embodiments, the epitaxial silicon-containing material 425 may be grown at a pressure between about 1 Torr and about 100 Torr. Pressure may impact growth rate and crystal quality of the epitaxial silicon-containing material 425. Poor crystal quality may allow more diffusion from the first source/drain material 415 to the epitaxial silicon-containing material 425. As such, the epitaxial silicon-containing material 425 may be grown at a pressure greater than or about 3 Torr, and may be grown at a pressure greater than or about 4 Torr, greater than or about 5 Torr, greater than or about 7 Torr, greater than or about 10 Torr, greater than or about 15 Torr, greater than or about 20 Torr, greater than or about 30 Torr, greater than or about 40 Torr, greater than or about 50 Torr, greater than or about 75 Torr, greater than or about 100 Torr, or more.

The present technology may grow epitaxial silicon-containing material 425 that may be characterized by reduced dopant incorporation. In embodiments, the epitaxial silicon-containing material 425 may be characterized by a dopant incorporation of less than or about 1E20 atoms/cm³, and may be characterized by a dopant incorporation of less than or about 1E19 atoms/cm³, less than or about 5E18 atoms/cm³, less than or about 1E18 atoms/cm³, less than or about 8E17 atoms/cm³, less than or about 6E17 atoms/cm³, less than or about 4E17 atoms/cm³, less than or about 2E17 atoms/cm³, less than or about 1E17 atoms/cm³, or less.

As such, in embodiments, method 300 may utilize both the barrier layer 420 and formation techniques (e.g., precursors, temperature, and/or pressure) to further reduce and/or prevent diffusion. It is also contemplated that only the barrier layer 420 or the formation techniques may be used, such as to provide a desired dopant profile in the epitaxial silicon-containing material 425.

In embodiments, operation 320 may be performed in the same or a different processing region from optional operation 305. If performed in the same processing region, residual dopant material may be present in the chamber and may nevertheless incorporate dopant material in the epitaxial silicon-containing material 425. To further reduce and/or prevent dopant incorporation in the epitaxial silicon-containing material 425, the structure 400 may be moved to a different processing region, such as of a different semiconductor processing chamber, to perform operation 320. Alternatively, and as previously discussed, method 300 may include performing a clean at optional operation 310 to remove at least a portion of residual material or contamination from the processing region, including the dopant incorporated in the first source/drain material 415.

As illustrated in FIG. 4D, optional operation 325 of method 300 may include forming a second barrier layer 430. The second barrier layer 430 may be formed over or directly on the epitaxial silicon-containing material 425. However, it is again contemplated that the second barrier layer 430 may be separated from the epitaxial silicon-containing material 425 by one or more intervening layers. The second barrier layer 430 may include any of the features or characteristics of the barrier layer 420, which may be a first barrier layer.

As illustrated in FIG. 4E, optional operation 330 of method 300 may include forming second source/drain material 435. The second source/drain material 435 may be formed over or directly on the second barrier layer 430. However, it is again contemplated that the second source/drain material 435 may be separated from the second barrier layer 430 by one or more intervening layers. The second source/drain material 435 may include any of the features or characteristics of the first source/drain material 415.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
forming a barrier layer on a first source/drain material disposed on a substrate housed within a processing region of a semiconductor processing chamber, wherein the first source/drain material is doped with a dopant; and
growing an epitaxial silicon-containing material on the barrier layer, wherein the barrier layer reduces an amount of diffusion of the dopant from the first source/drain material into the epitaxial silicon-containing material.

2. The semiconductor processing method of claim 1, wherein forming the barrier layer comprises:
providing one or more deposition precursors to the processing region of the semiconductor processing chamber; and
contacting the substrate with the one or more deposition precursors, wherein the contacting forms the barrier layer.

3. The semiconductor processing method of claim 1, wherein the dopant comprises a Group V element.

4. The semiconductor processing method of claim 1, wherein the dopant comprises phosphorous (P).

5. The semiconductor processing method of claim 1, wherein the barrier layer is characterized by a thickness of less than or about 500 Å.

6. The semiconductor processing method of claim 1, wherein the barrier layer is characterized by a thickness of greater than or about 10 Å.

7. The semiconductor processing method of claim 1, wherein the barrier layer comprises one or more silicon-containing materials.

8. The semiconductor processing method of claim 7, wherein the one or more silicon-containing materials are doped with a Group III-V element.

9. The semiconductor processing method of claim 1, wherein the barrier layer comprises a carbon-doped silicon-containing material.

10. The semiconductor processing method of claim 1, wherein the barrier layer is formed at a temperature of less than or about 600 ° C.

11. The semiconductor processing method of claim 1, further comprising:
prior to forming the barrier layer, forming the first source/drain material on the substrate in the processing region of the semiconductor processing chamber.

12. The semiconductor processing method of claim 11, further comprising:
subsequent to forming the first source/drain material on the substrate in the processing region of the semiconductor processing chamber, performing a clean to remove residual dopant from the processing region.

13. The semiconductor processing method of claim 1, wherein a pressure within the processing region is maintained at greater than or about 5 Torr while growing the epitaxial silicon-containing material.

14. A semiconductor processing method comprising:
forming a first source/drain material on a substrate in a processing region of a semiconductor processing chamber, wherein the first source/drain material is doped with a dopant; and
growing an epitaxial silicon-containing material on the first source/drain material, wherein the epitaxial silicon-containing material is formed at a temperature of less than or about 600 ° C.

15. The semiconductor processing method of claim 14, further comprising:
forming a barrier layer of a silicon-containing material on the first source/drain material.

16. The semiconductor processing method of claim 14, wherein the epitaxial silicon-containing material is characterized by a dopant concentration of less than or about 1E20 atoms/cm³.

17. The semiconductor processing method of claim 14, wherein:
the first source/drain material is formed in a first semiconductor processing chamber; and
the epitaxial silicon-containing material is grown in a second semiconductor processing chamber.

18. A semiconductor processing method comprising:
forming a first source/drain material on a substrate in a processing region of a semiconductor processing chamber, wherein the first source/drain material is doped with a Group V element;
performing a clean to remove residual Group V element from the processing region;
forming a barrier layer on the first source/drain material, wherein the barrier layer is formed at a first temperature of less than or about 600 ° C.; and
growing an epitaxial silicon-containing material on the barrier layer, wherein the barrier layer controls an amount of diffusion of the Group V element from the first source/drain material into the epitaxial silicon-containing material.

19. The semiconductor processing method of claim 18, wherein:
the barrier layer comprises one or more silicon-containing materials; and
the barrier layer is characterized by a thickness of less than or about 500 Å.

20. The semiconductor processing method of claim 18, wherein the epitaxial silicon-containing material is grown at a second temperature greater than the first temperature.
